(19) United States
(12) Patent Application Publication
(10) Pub. No.: US 2023/0261115 A1
(43) Pub. Date: Aug. 17, 2023

(54) AREA SELECTIVE AND DE-SELECTIVE ATOMIC LAYER DEPOSITION OF 360-DEGREE TWO-DIMENSIONAL CHANNELS

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/672,636

(22) Filed: Feb. 15, 2022

(51) Int. Cl. H01L 29/786; H01L 21/321; H01L 29/66; H01L 21/3105; H01L 21/027

(52) U.S. Cl. CPC H01L 29/78642; H01L 21/3212; H01L 29/66045; H01L 21/31056; H01L 21/0273; H01L 21/823418

(57) ABSTRACT

A method for fabricating semiconductor devices, may include forming a dielectric having a central portion with top and bottom surfaces thereof. A first sacrificial material and a second sacrificial material may be formed on the top and bottom surfaces, respectively, of the dielectric. End portions of the dielectric may be replaced with a first source/drain (S/D) metal and a second S/D metal. The central portion of the dielectric may be exposed at least by removing the first sacrificial material and second sacrificial material. Two-dimensional (2D) material may be selectively grown around the central portion of the dielectric

### TECHNICAL FIELD

The present invention relates generally to the field of manufacturing semiconductor devices, more particularly to the field of designing and manufacturing three dimensional (3D) devices.

### BACKGROUND

In the manufacture of semiconductor devices (especially on the microscopic scale), various fabrication processes are executed, such as film-forming depositions, etch mask creation, patterning, material etching and removal, and doping treatments. These processes are performed repeatedly to form desired semiconductor device elements on a substrate. Conventional microfabrication techniques only manufacture transistors in one active device plane, while wiring or metallization is formed above the active device plane. Such devices are accordingly characterized as two-dimensional (2D) circuits, thereby manufactured using 2D fabrication techniques. Although scaling efforts have greatly increased the number of transistors per unit area in 2D circuits, these 2D fabrication techniques are approaching physical atomic limitations with single digit nanometer semiconductor device fabrication nodes. Semiconductor device fabricators have expressed a desire for different manufacturing techniques and configurations of devices to increase density of semiconductor circuitry.

### SUMMARY

As technology continues to advance and transistor features of planar devices approach theoretical limits, there is a growing desire to find new structures, materials, and/or processes that advance Moore's Law without compromising various aspects. An area of growing interest is using nanosheets with materials that are no thicker than several hundreds of nanometers down to 2D semiconductors having thicknesses of one atomic layer. Fabricating semiconductor devices, such as transistors and memories using these types of materials may pose great challenges for manufacturers. Accordingly, there is a desire to find different materials and structures that can be fabricated using reliable processes. Moreover, fabrication processes of stacking a plurality of devices to manufacture a three-dimensional (3D) device allow for high density circuits. Although scaling efforts have greatly increased the number of transistors per unit area in 2D semiconductor devices, improvements in manufacturing a 3D device with higher density circuits at reduced cost remains desired.

To solve these problems, according to certain aspects, embodiments herein relate to techniques for improving processes of forming a 360-degree 2D channel by an area-selective deposition of 2D materials. Some embodiments relate to methods for forming 360-degree 2D channels in an N device tall stack in one process. In some embodiments, (area) selective and (area) de-selective (or non-selective) atomic layer deposition (ALD) of 360-degree 2D channels may be performed.

Some embodiments relate to methods for forming 360-degree 2D channels by performing selective and de-selective ALD deposition in a horizontal nanosheet with one device, using two different dielectric materials. Some embodiments relate to methods for forming 360-degree 2D channels by performing selective and de-selective ALD deposition in a horizontal nanosheet with two devices, using two different dielectric materials. For example, transition metal oxides, such as MoO₃, Nb₂O₅, or WO₃, may be used as one of the two dielectric materials in a selective area (or region) for growing 2D materials, while Al₂O₃ or HfO₂ may be used as the other of the two dielectric materials in a de-selective area (or region) for effectively blocking the growth of 2D materials.

Some embodiments relate to methods for utilizing an enclosure of a cavity of a de-selective (non-selective) area to perform an area-selective deposition of a 2D channel in a gate-all-around (GAA) nanosheet. 2D materials may be selectively deposited or grown in a two material system including (1) one selective area (or region) and (2) one de-selective area (or region). In some embodiments, a selective area and a de-selective area may be formed using two different dielectric materials as described above. In some embodiments, a 2D selective area may be formed in a SiO₂ carrier nanosheet with enclosure of Al₂O₃ as a de-selective (or non-selective) area, using ALD deposition of 2D materials. Examples of 2D materials include, but are not limited to, (1) W-based 2D materials (e.g., WS₂, WSe₂, WTe₂), (2) Mo-based 2D materials (e.g., MoS₂, MoSe₂, MoTe₂), or (3) other 2D materials such as HfS₂, ZrS₂, TiS₂, GaSe, InSe, phosphorene.

Some embodiments relate to methods for forming 360-degree 2D channels by performing selective and de-selective ALD deposition in a horizontal nanosheet with one device (e.g., one transistor), using a selective area of SiO₂ and a de-selective area of Al₂O₃. Some embodiments relate to methods for forming 360-degree 2D channels by performing selective and de-selective ALD deposition in a horizontal nanosheet with multiple devices (e.g., two transistors).

Methods according to some embodiments may be applied to a flow of forming any 2D material in a GAA 3D stacked nanosheet. For example, 2D materials may be formed in a GAA 3D stacked nanosheet included in a complementary vertical field effect transistor (CFET) structure in which two transistors have opposite conductive types (a P-type or N-type).

Embodiments in the present disclosure may provide useful techniques for forming a 360-degree 2D channel in an N device tall stack in one process (e.g., N=2), thereby enabling higher density circuits to be produced at reduced cost. The 360-degree 2D channel may be formed in one process by selectively depositing or growing 2D materials in a 2 material system including one selective area of one material and one de-selective area of the other material.

One embodiment of a semiconductor device may include a transistor structure including a first source/drain (S/D) metal, a second S/D metal, and a dielectric extending between and coupled to the first S/D metal and second S/D metal. A 2D material may be around the dielectric. A high-k dielectric may be around the 2D material, and a gate metal may be around the high-k dielectric.

The 2D material may be a material selected from the group consisting of: WS₂, WSe₂, WTe₂, MoS₂, MoSe₂, MoTe₂, HfS₂, ZrS₂, TiS₂, GaSe, InSe, phosphorene, and combinations thereof. The transistor structure may be embedded in a second dielectric. The 2D material may directly contact a majority portion of the dielectric and is not formed on the second dielectric. In an embodiment, the gate metal may be formed in an opening of the second dielectric.

The semiconductor device may further include second transistor including a third source/drain (S/D) metal, a fourth S/D metal, and a second dielectric extending between and coupled to the third S/D metal and fourth S/D metal. A second 2D material may be around the second dielectric. A second high-k dielectric may be around the second dielectric. A second gate metal may be around the second high-k dielectric.

The second transistor may be embedded in the second dielectric. The second transistor may be disposed above the first transistor, and the first and second transistors may have opposite conductive types.

The dielectric may be silicon dioxide (SiO2), and the second dielectric may be aluminium oxide (Al2O3).

One embodiment of a method for fabricating semiconductor devices may include forming a dielectric having a central portion with top and bottom surfaces thereof. A first sacrificial material and a second sacrificial material may be formed on the top and bottom surfaces, respectively, of the dielectric. End portions of the dielectric may be replaced with a first source/drain (S/D) metal and a second S/D metal. The central portion of the dielectric may be exposed at least by removing the first sacrificial material and second sacrificial material. A 2D material may be selectively grown around the central portion of the dielectric.

In an embodiment, the 2D material is a material selected from the group consisting of: WS2, WSe2, WTe2, MoS2, MoSe2, MoTe2, HfS2, ZrS2, TiS2, GaSe, InSe, phosphorene, and combinations thereof.

The method may further include selectively growing a high-k dielectric around the 2D material, and growing a gate metal around the high-k dielectric.

In exposing the central portion, the process may include forming a cavity defined by a second dielectric that surrounds the central portion, where the 2D material does not contact the second dielectric.

The process may further include non-selectively growing a high-k dielectric on the second dielectric, and growing a first gate metal in the cavity of the second dielectric.

Still yet, the process may include forming a third dielectric having a central portion with top and bottom surfaces thereof, forming a third sacrificial material and a fourth sacrificial material on the top and bottom surfaces, respectively, of the third dielectric, replacing end portions of the second dielectric with a third source/drain (S/D) metal and a fourth S/D metal, respectively, exposing the central portion of the dielectric at least by removing the third sacrificial material and fourth sacrificial material, and selectively growing a 2D material around the central portion of the second dielectric.

Exposing the central portion of the second dielectric may include forming a cavity of the third dielectric that surrounds the central portion of the second dielectric, wherein the second 2D material does not contact the third dielectric.

The dielectric may be silicon dioxide (SiO2), and the second dielectric is aluminium oxide (Al2O3).

An embodiment of a semiconductor device may include a first transistor and a second transistor. The first transistor may include a first dielectric, a first 2D material around the first dielectric, a first source/drain (S/D) metal coupled to one end of the first 2D material, a second S/D metal coupled to the other end of the first 2D material, and a first gate metal around the first 2D material. The second transistor may include a second dielectric, a second 2D material around the second dielectric, a second source metal coupled to one end of the second 2D material, a second drain metal coupled to the other end of the second 2D material, and a second gate metal around the second 2D material. The second transistor may be disposed above the first transistor, and the first and second transistors have opposite conductive types.

The first transistor may further include a first high-k dielectric around the first 2D material. The first gate metal may be disposed around the first high-k dielectric. The second transistor may further include a second high-k dielectric disposed around the second 2D material, and the second gate metal may be disposed around the second high-k dielectric. The first transistor and the second transistor may be embedded in a third dielectric.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A-1D illustrate a flowchart of a process for forming example semiconductor devices, in accordance with some embodiments.

FIGS. 2A and 2B show cross-sectional views of semiconductor devices at completion of the process of FIGS. 1A-1D, in accordance with some embodiments.

FIGS. 3A-3N show cross-sectional views of a semiconductor device being manufactured at different stages of the process of 1A-1D, in accordance with some embodiments.

FIGS. 4A-4D illustrate a flowchart of a process for forming example semiconductor devices, in accordance with some embodiments.

FIGS. 5A and 5B show cross-sectional views of semiconductor devices at completion of the process of FIGS. 4A-4D, in accordance with some embodiments.

FIGS. 6A-6N show cross-sectional views of a semiconductor device being manufactured at different stages of the process of 4A-4D, in accordance with some embodiments.

### DETAILED DESCRIPTION

Reference will now be made to the figures, which for the convenience of visualizing the 3D fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, although most of the figures show various layers in a planar and/or rectangular configuration, other shapes are also contemplated, and indeed the techniques described herein may be implemented in any shape or geometry. As an example, non-continuous contact shapes, such as arcs or polygonal trenches, may be adjacent to, partially surround, or fully surround a central channel in addition to or as an alternative to the ring shapes illustrated. In addition, examples in which two transistors or devices are shown stacked on top of one another are shown for illustrative purposes only, and for the purposes of simplicity. Indeed, the techniques described herein may provide for one to any number N stacked devices. Further, although the devices fabricated using these techniques are shown as transistors, it should be understood that any type of electric electronic device may be manufactured using such techniques, including but not limited to transistors, variable resistors, resistors, and capacitors.

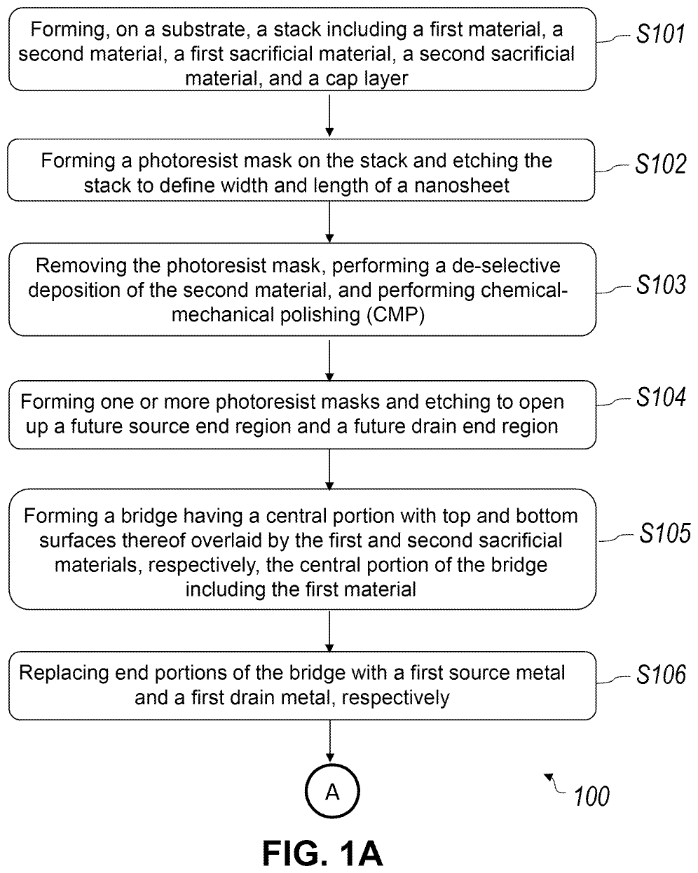

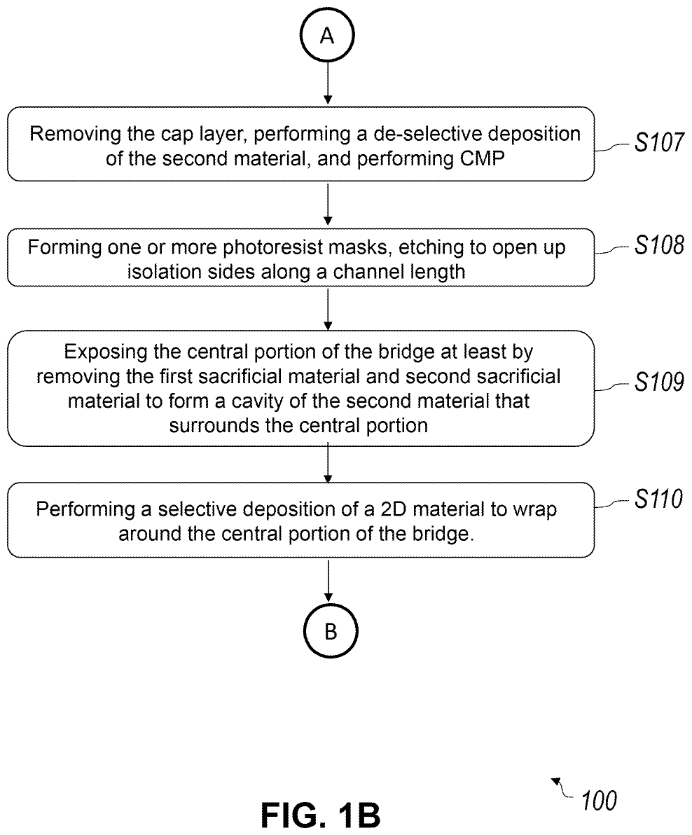

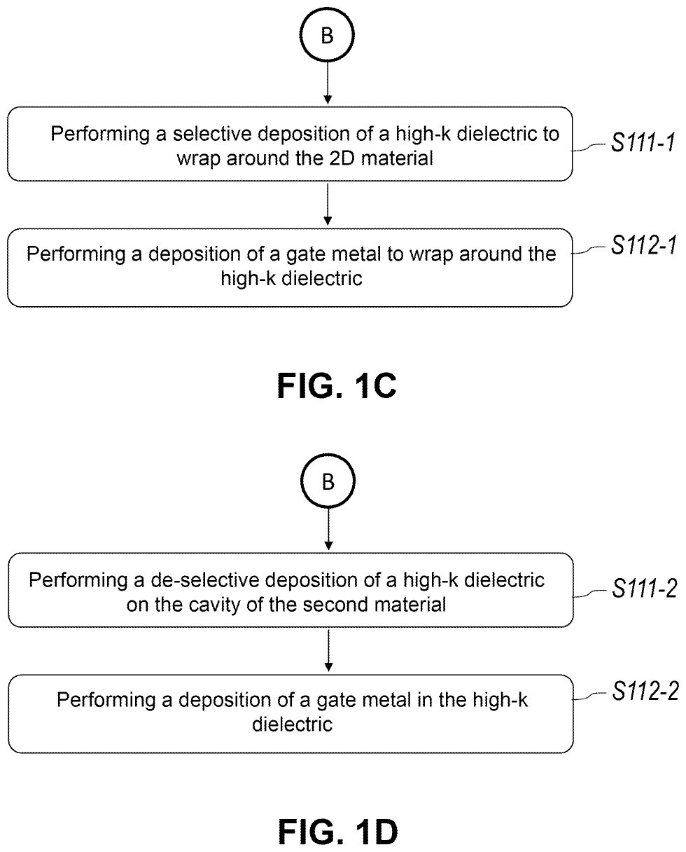

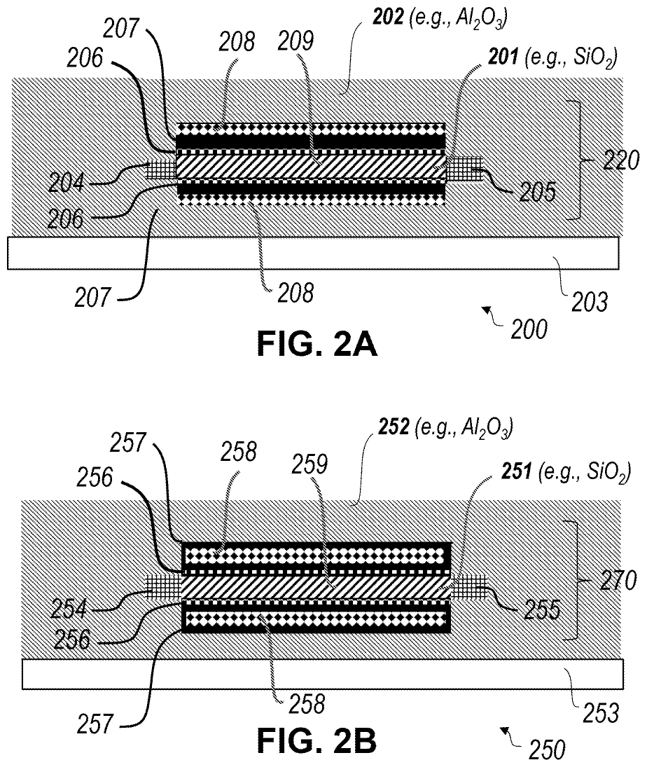

FIG. 1 illustrates a flowchart of a process 100 for forming an example semiconductor device (e.g., transistor), in accordance with some embodiments. It is noted that the process 100 is merely an example, and is not intended to limit the present disclosure. Accordingly, it is understood that additional operations may be provided before, during, and after the process 100 of FIG. 1, and that some other operations may only be briefly described herein. In some embodiments, the process 100 may form 360-degree 2D channels by performing (area) selective and (area) de-selective ALD deposition in a horizontal nanosheet with one device, using two different materials. The two different materials may be two different dielectric materials (see FIGS. 2A and 2B).

FIGS. 2A and 2B show cross-sectional views of semiconductor devices at completion of the process of FIGS. 1A-1D, in accordance with some embodiments.

Referring to FIG. 2A, in some embodiments, the process 100 may form a semiconductor device 200 including a substrate 203 and a transistor 220. The transistor 220 may include a dielectric material 209, a 2D material 206, a source metal 204, a drain metal 205, a high-k dielectric 207, and a gate metal 208. The dielectric material may extend between the source metal 204 and drain metal 205, as further described herein. The dielectric material 209 may include a first material 201 (e.g., SiO₂). The 2D material 206 may be disposed around the dielectric material 209, thereby forming a 360-degree 2D channel. The source metal 204 may be coupled to one end of the 2D material 206. The drain metal 205 may be coupled to the other end of the 2D material 206. The high-k dielectric 207 may be disposed around the 2D material 206 (i.e., be disposed by deposition, grown, or otherwise on each of the surfaces of the 2D material). The gate metal 208 may be disposed around the high-k dielectric 207. In some implementations, the transistor 220 may be embedded in a second material (e.g., Al₂O₃). The 2D material 206 may directly contact a majority portion of the first material 201 and is not formed on the second material 202. The gate metal 208 may be formed in an opening of the second material 202. The first material 201 and the second material 202 may be two different dielectrics.

Referring to FIG. 2B, in some embodiments, the process 100 may form a semiconductor device 250 including a substrate 253 and a transistor 270. The transistor 270 may include a dielectric material 259, a 2D material 256, a source metal 254, a drain metal 255, a high-k dielectric 257, and a gate metal 258. The dielectric material 259 may include a first material 351 (e.g., SiO₂). The 2D material 256 may be disposed around the dielectric material 259, thereby forming a 360-degree 2D channel. The source metal 254 may be coupled to one end of the 2D material 256. The drain metal 255 may be coupled to the other end of the 2D material 256. A high-k dielectric 257 may be non-selectively grown on a second material 252 (e.g., Al₂O₃). A gate metal 258 may be grown in the cavity of the second material 252. In some implementations, the transistor 270 may be embedded in the second material 252. The 2D material 256 may directly contact a majority portion of the first material 251 and is not formed on the second material 252.

Referring to FIGS. 2A and 2B, the first material 201, 251 (e.g., SiO₂) and the second material 202, 252 (e.g., Al₂O₃) may be two different dielectrics. For example, the first material may be silicon oxide (SiO₂), or transition metal oxides such as MoO₃, Nb₂O₅, or WO₃, and the second material may be Al₂O₃ or HfO₂. The 2D material 206, 256 may be include, but is not limited to, WS₂, WSe₂, WTe₂, MoS₂, MoSe₂, MoTe₂, HfS₂, ZrS₂, TiS₂, GaSe, InSe, phosphorene, and other similar materials. These materials may be deposited by an atomic layer deposition (ALD) process and may be 5-15 angstroms thick, the thinness lending to their name −2D material. The materials may be annealed during or after the device formation process to recrystallize or grow the crystals and thereby improve electrical characteristics. For the sake of simplicity, the use of conductive dielectrics will be disclosed.

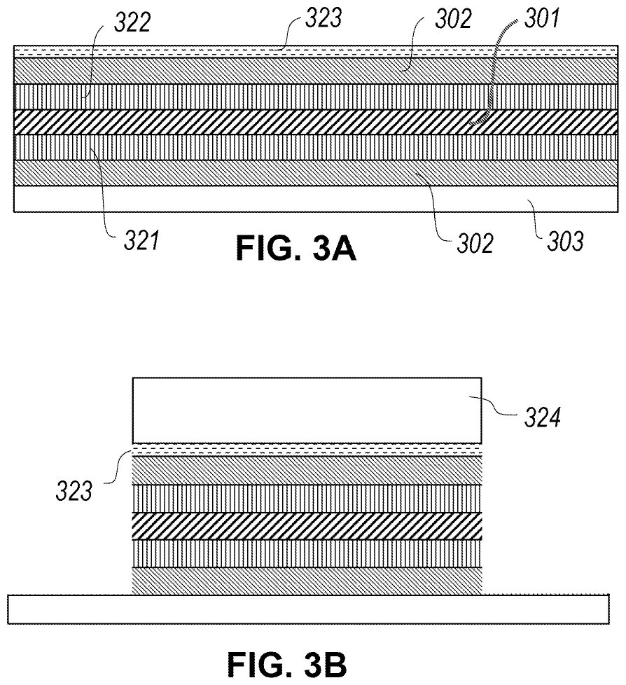

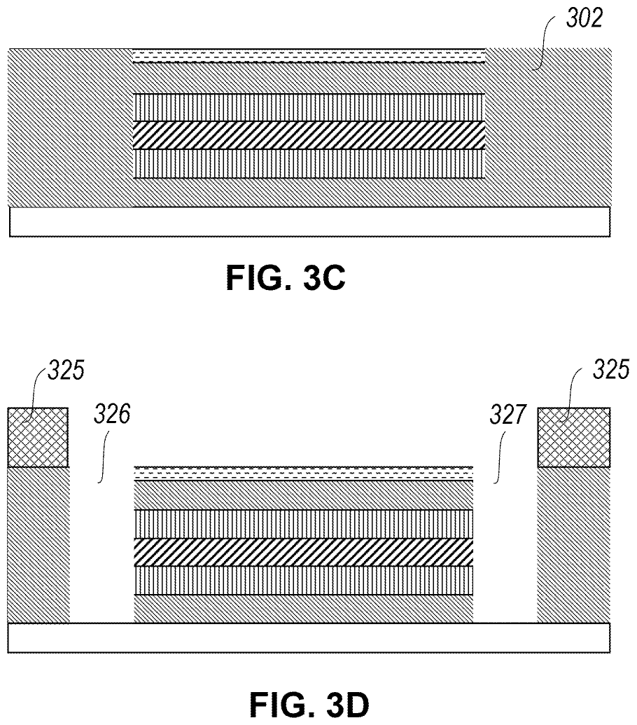

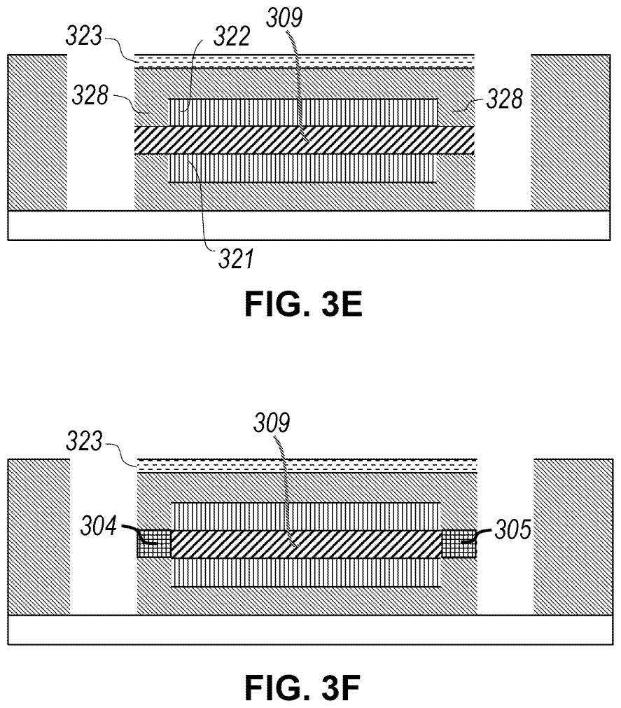

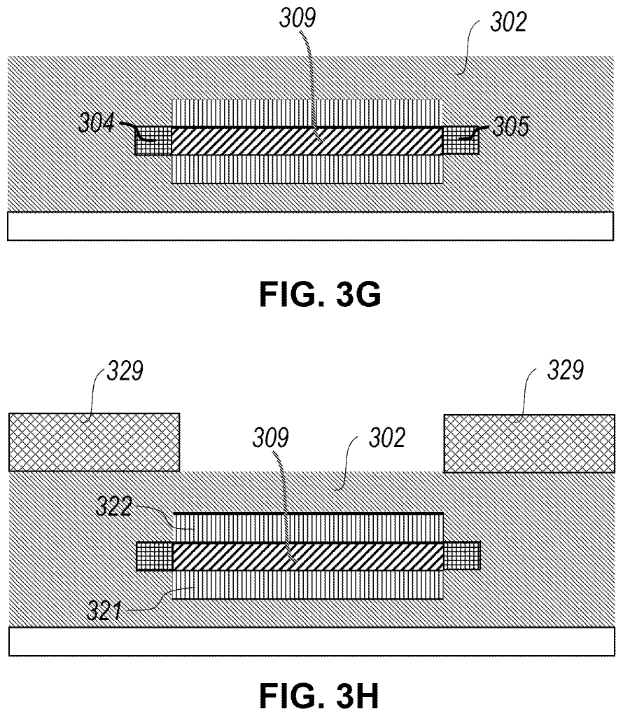

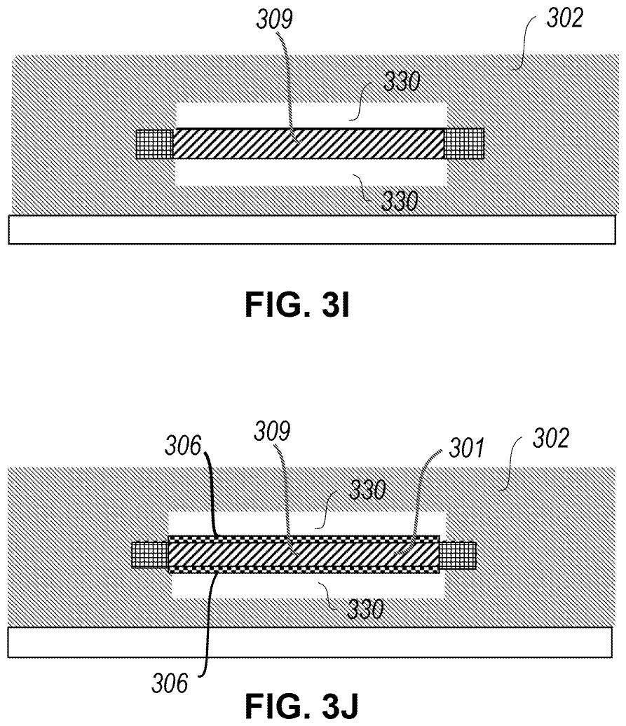

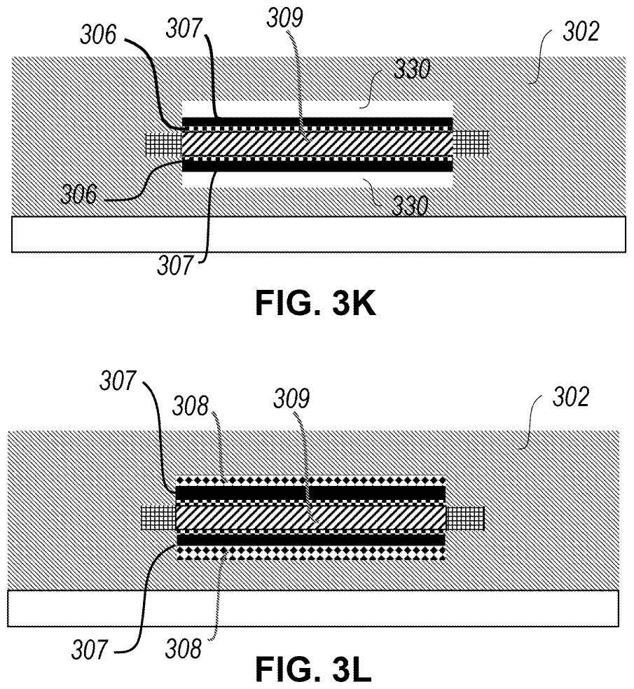

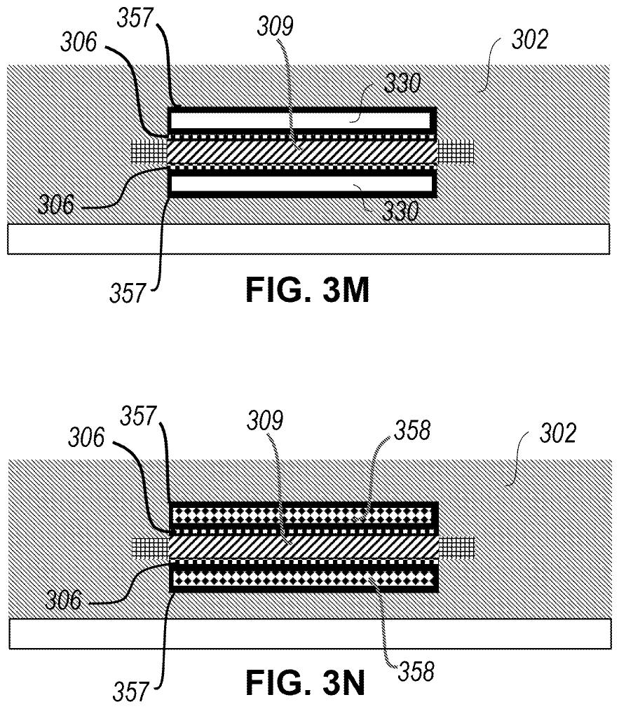

FIGS. 3A-3N show cross-sectional views of a semiconductor device being manufactured at different stages of the process of FIGS. 1A-1D, in accordance with some embodiments. Operations of the process 100 associated with cross-sectional views of an example semiconductor device at various fabrication stages as shown in FIGS. 3A-3N, respectively, are described in further detail herein below.

Corresponding to operation S101, FIG. 3A illustrates a resulting cross-sectional view of the semiconductor device after forming, on a substrate 303, a stack including a first material 301, one or more layers of a second material 302, a first sacrificial material 321, a second sacrificial material 322, and a cap layer 323. The stack may be created or formed on the substrate 303. A selective region may be formed using the first material 301, and a de-selective (non-selective) region may be formed using the second material 302. A 2D material (e.g., 2D material 306 in FIG. 3J) may be formed on a selective region (e.g., top and bottom regions of the first dielectric material 309 in FIG. 3J) with a de-selective region enclosure (e.g., a region enclosed by the second material 302 in FIG. 3J). In some embodiments, each of the first and second sacrificial materials 321 and 322 may include nitride. The first material 301 and the second material 302 may be different from each other. For example, the first material 301 may be silicon oxide (SiO₂) or transition metal oxides such as MoO₃, Nb₂O₅, or WO₃, and the second material 302 may be Al₂O₃ or HfO₂.

Corresponding to operation S102, FIG. 3B illustrates a resulting cross-sectional view of the semiconductor device after (1) forming a photoresist mask 324 on the stack (see FIG. 3A) and (2) etching the stack to define a width and length of the first material 301 (a majority of which will be surrounded by a 2D material) using the photoresist mask 324. In some embodiments, the photoresist mask 324 may be formed on the cap layer 323.

Corresponding to operation S103, FIG. 3C illustrates a resulting cross-sectional view of the semiconductor device after (1) removing the photoresist mask 324 (see FIG. 3B), (2) performing deposition of the second material 302 (so that a surface region of the second material 302 can be utilized as a de-selective area and the remainder of the second material can be utilized for isolation of the device from the environment and surrounding circuits), and (3) performing chemical-mechanical polishing (CMP).

Corresponding to operation S104, FIG. 3D illustrates a resulting cross-sectional view of the semiconductor device after (1) forming one or more photoresist masks 325 and (2) etching the second material 302 and/or the stack to open up a future source (end) region 326 and a future drain (end) region 327.

Corresponding to operation S105, FIG. 3E illustrates a resulting cross-sectional view of the semiconductor device after (1) removing the one or more photoresist masks 325 (see FIG. 3D), (2) performing an indent etch on each of the first sacrificial material and second sacrificial materials to remove end portions thereof 328, (3) performing deposition of the second material (as a de-selective area) in the removed end portions 328 such that a dielectric material 309 (formed of the first material 301) having a central portion with top and bottom surfaces thereof overlaid by the first sacrificial material 321 and the second sacrificial material 322, respectively, and (4) etching de-selective areas or regions (e.g., the second material 302 at both ends of the dielectric material 309) using a hard mask to be aligned to edges of the hard mask. The hard mask may be a nitride, oxide, or metal. The cap layer 323 may be used as a hard mask.

Corresponding to operation S106, FIG. 3F illustrates a resulting cross-sectional view of the semiconductor device after replacing end portions of the dielectric material 309 with a source metal 304 and a drain metal 305, respectively. The source metal 304 and the drain metal 305 may be formed so as to extend between the first sacrificial material 321 and the second sacrificial material 322. In some embodiments, the first material (as a selective area) at the end portions of the dielectric material 309 may be selectively indent-etched, followed by performing metal depositions to form the source metal 304 and the drain metal 305. Subsequently, the source metal 304 and drain metal 305 may be etched using a hard mask to be aligned to edges of the hard mask. The cap layer 323 may be used as a hard mask.

Corresponding to operation S107, FIG. 3G illustrates a resulting cross-sectional view of the semiconductor device after (1) removing the cap layer 323 (see FIG. 3F), (2) performing deposition of the second material 302 (as a de-selective area) in the removed area, and (3) performing CMP.

Corresponding to operation S108, FIG. 311 illustrates a resulting cross-sectional view of the semiconductor device after (1) forming one or more photoresist masks 329 and (2) etching a resultant structure of operation S107 using the one or more photoresist masks 329 configured to open up a perimeter of the central portion of the dielectric material 309. For example, the photoresist masks 329 can cause at least four surfaces of the central portion of the dielectric material 309 (e.g., top and bottom surfaces of the dielectric material 309 that are in contact with the first and second sacrificial materials 321 and 322, respectively, and sidewalls of the dielectric material 309 that face toward and away from the plane) to be exposed after removing the first and second sacrificial materials 321 and 322, which is described hereinbelow.

Corresponding to operation S109, FIG. 31 illustrates a resulting cross-sectional view of the semiconductor device after (1) exposing the central portion of the dielectric material 309 at least by removing the first sacrificial material 321 and the second sacrificial material 322 (see FIG. 311) to form a bridge-like structure of the dielectric material 309, and (2) removing the one or more photoresist masks 329. As such, a cavity 330 of the second material 302 that surrounds the central portion of the dielectric material 309 (e.g., 360 degree) can be formed. In this manner, the first material 301 (as a selective area) of the central portion may be exposed 360 degree in the cavity 330 of the second material (as a de-selective area) to perform a 2D material deposition in operation S110.

Corresponding to operation S110, FIG. 3J illustrates a resulting cross-sectional view of the semiconductor device after (1) selectively growing a 2D material 306 to be disposed around the central portion of the dielectric material 309. The 2D material 306 may be selectively grown on the first material 301 (of the central portion of the dielectric material 309). The deposition of the 2D material 306 may be performed on a selective region of the first material 301. The deposition of the 2D material 306 may be performed by atomic layer deposition (ALD). In some embodiments, the 2D material 306 does not contact the second material 302. Some example 2D materials for use in forming the channel include, but are not limited to, WS₂, WSe₂, WTe₂, MoS₂, MoSe₂, MoTe₂, HfS₂, ZrS₂, TiS₂, GaSe, InSe, phosphorene, and other similar materials. These materials may be deposited by an atomic layer deposition (ALD) process and may be 5-15 angstroms thick, the thinness lending to their name −2D material. The materials may be annealed during or after the device formation process to recrystallize or grow the crystals and thereby improve electrical characteristics. For the sake of simplicity, the use of conductive dielectrics will be disclosed.

In one embodiment, the process 100 may further include operations S111-1 and S112-1 as shown in FIG. 1C. As a result of operations S111-1 and S112-1, the process 100 may form a semiconductor device similar to the device 200 as shown in FIG. 2A.

Corresponding to operation S111-1, FIG. 3K illustrates a resulting cross-sectional view of the semiconductor device after selectively growing a high-k dielectric 307 to be disposed around the 2D material 306 (e.g., 360 degrees). In some embodiments, a 360-degree deposition of the high-k gate dielectric 307 may be performed on the 2D material 306.

Corresponding to operation S112-1, FIG. 3L illustrates a resulting cross-sectional view of the semiconductor device after growing a gate (electrode) metal 308 to be disposed around the high-k dielectric 307 (e.g., 360 degrees). In some embodiments, a 360-degree deposition of the gate electrode metal 308 may be performed on the high-k gate dielectric 307.

Alternatively, the process 100 may include operations S111-2 and S112-2 as shown in FIG. 1D. As a result of operations S111-2 and S112-2, the process 100 may form a semiconductor device similar to the device 250 (see FIG. 2B).

Corresponding to operation S111-2, FIG. 3M illustrates a resulting cross-sectional view of the semiconductor device after non-selectively growing a high-k dielectric 357 on the second material 302 (as a de-selective area). In some embodiments, a (non-selective) deposition of the high-k dielectric 357 may be performed on the cavity 330 of the second material 302 (e.g., 360 degrees). A portion of the high-k dielectric 357 may be deposited on the 2D material 306. The non-selective deposition may be ALD of the high-k gate dielectric 357 on the cavity 330 of the second material 302 (as a de-selective area).

Corresponding to operation S112-2, FIG. 3N illustrates a resulting cross-sectional view of the semiconductor device after growing a gate (electrode) metal 358 in the cavity 330 of the second material 302 (e.g., 360 degrees). In some embodiments, a 360-degree deposition of the gate electrode metal 358 may be performed in the high-k gate dielectric 357.

Referring to FIGS. 3A-3N, some embodiments relate to methods for forming a 360-degree 2D channel (e.g., 2D material 306) in a single device tall stack (i.e., number of devices N=1) in one process. In some embodiments, selective and de-selective (or non-selective) atomic layer deposition (ALD) of 360-degree 2D channels may be performed. Some embodiments relate to methods for forming 360-degree 2D channels (e.g., 2D material 306) by performing a selective ALD deposition (see FIG. 3J) and a de-selective ALD deposition (see FIG. 3M) in a horizontal nanosheet with one device (e.g., transistor 220 in FIG. 2A or transistor 270 in FIG. 2B), using two different dielectric materials (e.g., first material 301 and second material 302). For example, silicon oxide (SiO₂), or transition metal oxides such as MoO₃, Nb₂O₅, or WO₃ may be used as the first material 301 in a selective area (or region) for growing 2D materials, while Al₂O₃ or HfO₂ may be used as the second material 302 in a de-selective area (or region) for effectively blocking the growth of 2D materials.

Some embodiments relate to methods for utilizing an enclosure of a cavity of a de-selective (non-selective) area (e.g., cavity 330 in FIGS. 3I-3K and 3M) to perform an area-selective deposition of a 2D channel (see FIG. 3J) in a gate-all-around (GAA) nanosheet (e.g., 360-degree deposition of gate electrode metal 308, 358 in FIGS. 3L and 3N. 2D materials (e.g., 2D material 306) may be selectively deposited or grown in a selective area (e.g., first material 301) of two material system including (1) the selective area (or region) and (2) a de-selective area (or region), e.g., second material 302. In some embodiments, a selective area and a de-selective area may be formed using two different dielectric materials as described above. In some embodiments, 2D materials may be formed in a selective area of a SiO₂ carrier nanosheet with enclosure of Al₂O₃ as a de-selective (or non-selective) area, using ALD deposition of the 2D materials. For example, referring to FIG. 3J, ALD deposition of the 2D material 306 may be performed on a selective area of the first material 301 (e.g., SiO₂) with enclosure of a de-selective area of the second material 302 (e.g., Al₂O₃).

Some embodiments relate to methods for forming 360-degree 2D channels (e.g., 2D material 306) by performing a selective ALD (see FIG. 3J) and a de-selective ALD deposition (see FIG. 3M) in a horizontal nanosheet with one device (e.g., transistor 220 in FIG. 2A or transistor 270 in FIG. 2B), using a selective area of the first material (e.g., SiO₂) and a de-selective area of the second material (e.g., Al₂O₃).

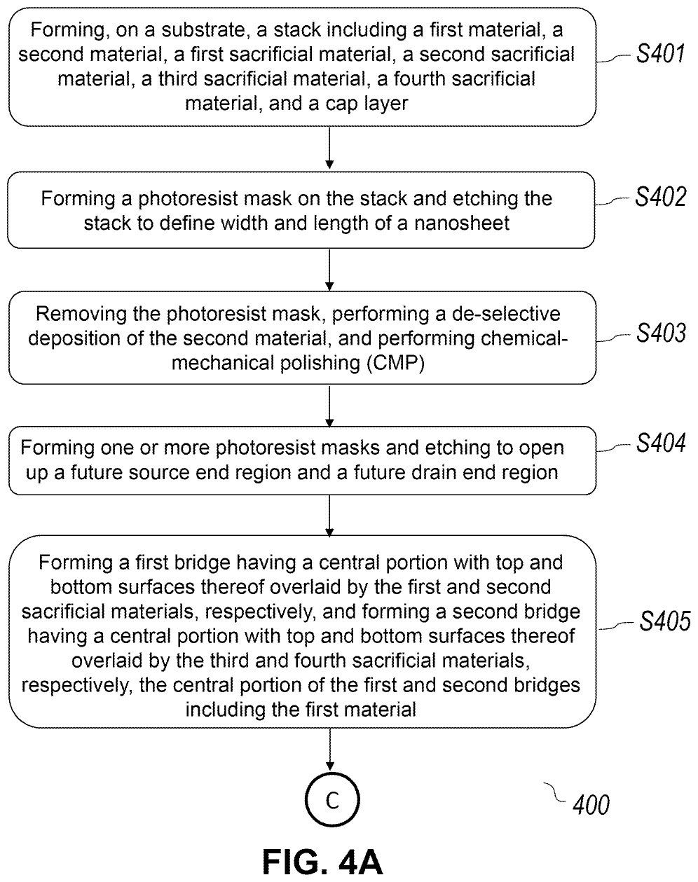

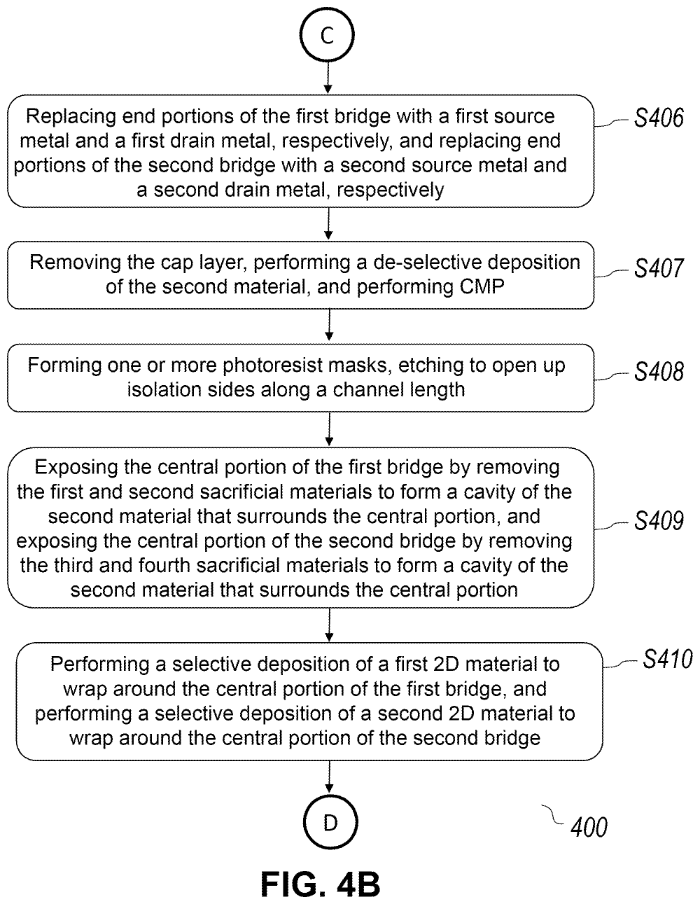

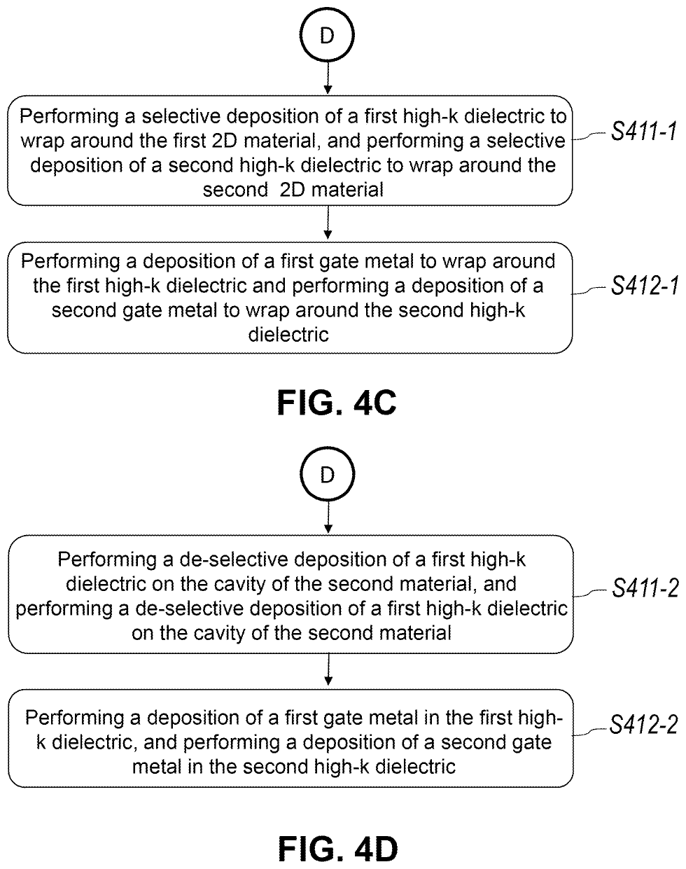

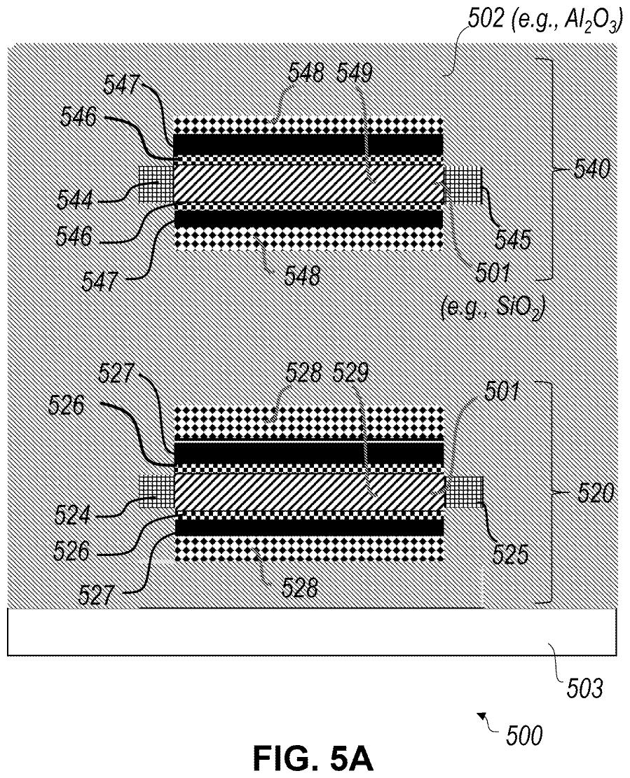

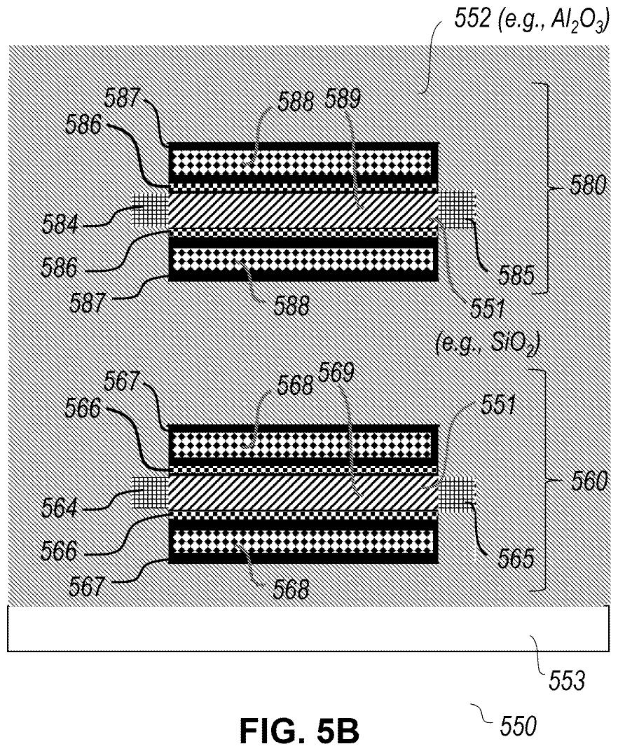

FIG. 4A-4D illustrates a flowchart of a process 400 for forming an example semiconductor device (e.g., transistor), in accordance with some embodiments. It is noted that the process 400 is merely an example, and is not intended to limit the present disclosure. Accordingly, it is understood that additional operations may be provided before, during, and after the process 400 of FIG. 4A-4D, and that some other operations may only be briefly described herein. In some embodiments, the process 400 may form 360-degree 2D channels by performing selective and de-selective ALD deposition in a horizontal nanosheet with two devices, using two different materials. The two different materials may be two different dielectric materials (see FIGS. 5A and 5B).

Methods according to some embodiments may be applied to a flow of forming any 2D material in a GAA 3D stacked nanosheet with N devices (e.g., N=2). For example, 2D material may be formed in a GAA 3D stacked nanosheet included in a complementary vertical field effect transistor (CFET) structure in which two transistors have opposite conductive types (a P-type or N-type).

FIGS. 5A and 5B show cross-sectional views of semiconductor devices at completion of the process of FIGS. 4A-4D, in accordance with some embodiments.

Referring to FIG. 5A, in some embodiments, the process 400 may form a semiconductor device 500. In some embodiments, the semiconductor device 500 may be a complementary vertical field effect transistor (CFET) structure including a stack of layers. The semiconductor device 500 may include a substrate 503, a first transistor 520 and a second transistor 540. The first transistor 520 may include a first dielectric material 529 (e.g., a dielectric, and in an embodiment, an elongated structure), a first 2D material 526, a first source metal 524, a first drain metal 525, a first high-k dielectric 527, and a first gate metal 528. The first dielectric material 529 may include a first material 501 (e.g., SiO₂). The first 2D material 526 may be disposed around the first dielectric material 529, thereby forming a 360-degree 2D channel. The first source metal 524 may be coupled to one end of the first 2D material 526. The first drain metal 525 may be coupled to the other end of the first 2D material 526. The first high-k dielectric 527 may be disposed around the first 2D material 526. The first gate metal 528 may be disposed around the first high-k dielectric 527. In some implementations, the first transistor 520 may be embedded in a second material 502 (e.g., Al₂O₃). The first 2D material 526 may directly contact a majority portion of the first material 501 such that the first material 501 is not formed on the second material 502. The first gate metal 528 may contact the second material 502.

The second transistor 540 may be disposed above the first transistor 520, and the first and second transistors may have opposite conductive types (e.g., a P-type or N-type). The second transistor 540 may include a second dielectric material 549, a second 2D material 546, a second source metal 544, a second drain metal 545, a second high-k dielectric 547, and a second gate metal 548. The second dielectric material 549 may include the first material 501. The second 2D material 546 may be disposed around the dielectric material 549, thereby forming a 360-degree 2D channel. The second source metal 544 may be coupled to one end of the second 2D material 546. The second drain metal 545 may be coupled to the other end of the second 2D material 546. The second high-k dielectric 547 may be disposed around the second 2D material 546. The second gate metal 548 may be disposed around the second high-k dielectric 547. In some implementations, the second transistor 540 may be embedded in the second material. The second 2D material 546 may directly contact a majority portion of the first material 501 and is not formed on the second material 502. The second gate metal 548 may be formed in an opening of the second material 502.

Referring to FIG. 5B, in some embodiments, the process 400 may form a semiconductor device 550. In some embodiments, the semiconductor device 550 may be a CFET structure including a stack of layers. The semiconductor device 550 may include a substrate 553, a first transistor 560 and a second transistor 580. The first transistor 560 may include a first dielectric material 569, a first 2D material 566, a first source metal 564, a first drain metal 565, a first high-k dielectric 567, and a first gate metal 568. The first dielectric material 569 may include a first material 551. The first 2D material 566 may be disposed around the first dielectric material 569, thereby forming a 360-degree 2D channel. The first source metal 564 may be coupled to one end of the first 2D material 566. The first drain metal 565 may be coupled to the other end of the first 2D material 566. A first high-k dielectric 567 may be non-selectively grown on a second material 552. A first gate metal 568 may be grown in the cavity of the second material 552. In some implementations, the first transistor 560 may be embedded in the second material 552. The first 2D material 566 may directly contact a majority portion of the first material 551 and is not formed on the second material 552.

The second transistor 580 may be disposed above the first transistor 560, and the first and second transistors may have opposite conductive types (e.g., a P-type or N-type). The second transistor 580 may include a second dielectric material 589, a second 2D material 586, a second source metal 584, a second drain metal 585, a second high-k dielectric 587, and a second gate metal 588. The second dielectric material 589 may include the first material 551. The second 2D material 586 may be disposed around the second dielectric material 589, thereby forming a 360-degree 2D channel. The second source metal 584 may be coupled to one end of the second 2D material 586. The second drain metal 585 may be coupled to the other end of the second 2D material 586. A second high-k dielectric 587 may be non-selectively grown on the second material 552. A second gate metal 588 may be grown in the cavity of the second material 552. In some implementations, the second transistor 580 may be embedded in the second material 552. The second 2D material 586 may directly contact a majority portion of the first material 551 and is not formed on the second material 552.

Referring to FIGS. 5A and 5B, the first material 501, 551 (e.g., SiO₂) and the second material 502, 552 (e.g., Al₂O₃) may be two different dielectrics. For example, the first material may be silicon oxide (SiO₂), or transition metal oxides such as MoO₃, Nb₂O₅, or WO₃, and the second material may be Al₂O₃ or HfO₂. The 2D material 526, 546, 566, 586 may include, but is not limited to, WS₂, WSe₂, WTe₂, MoS₂, MoSe₂, MoTe₂, HfS₂, ZrS₂, TiS₂, GaSe, InSe, phosphorene, and other similar materials.

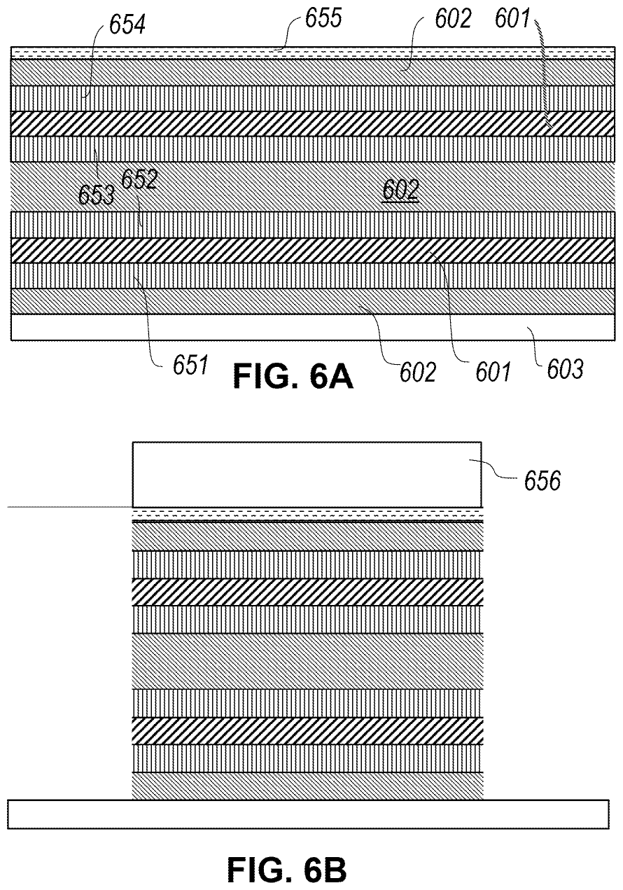

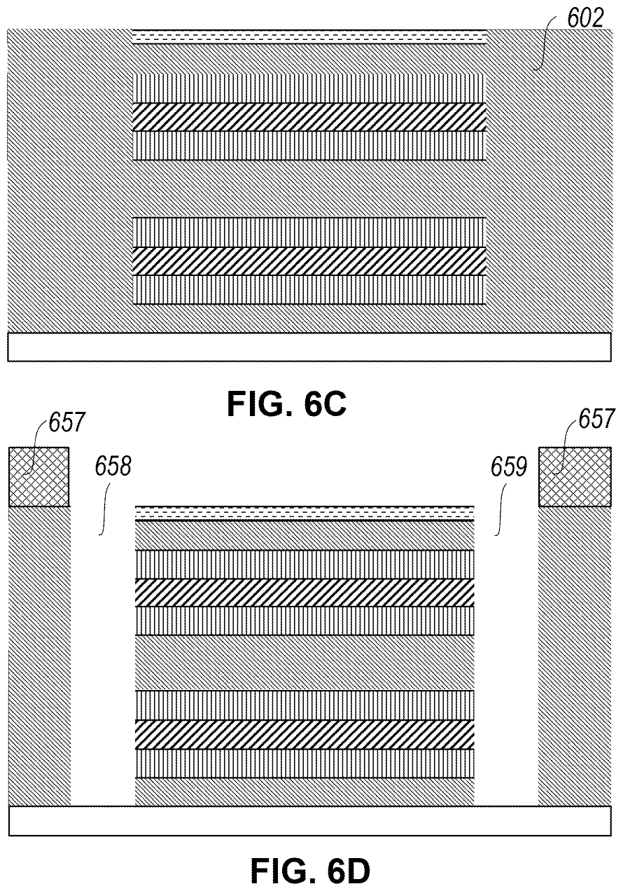

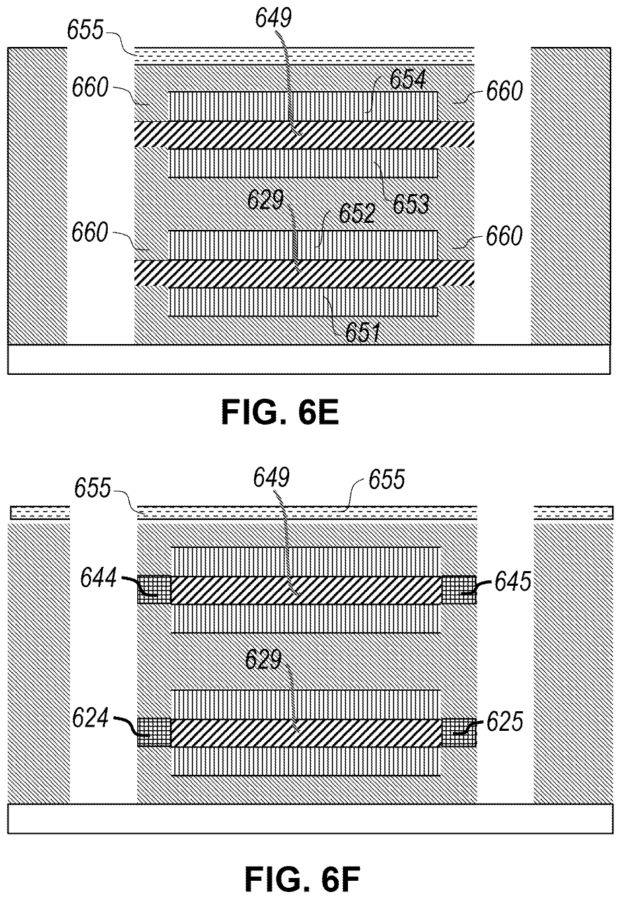

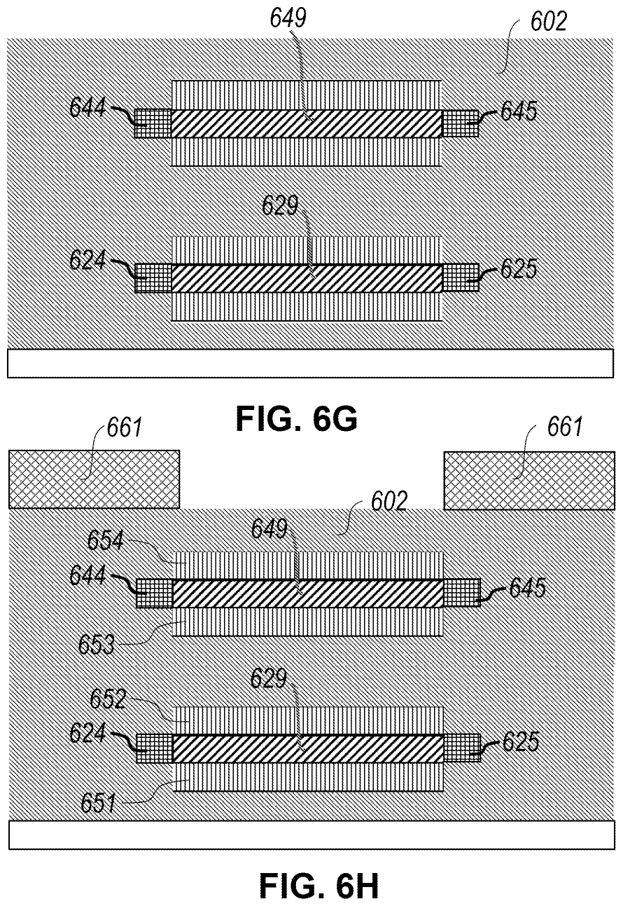

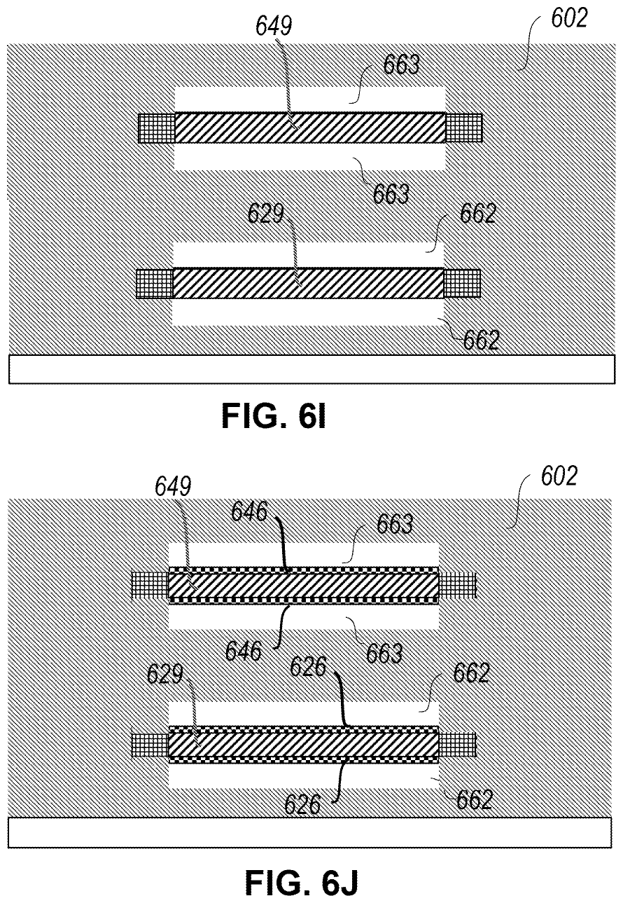

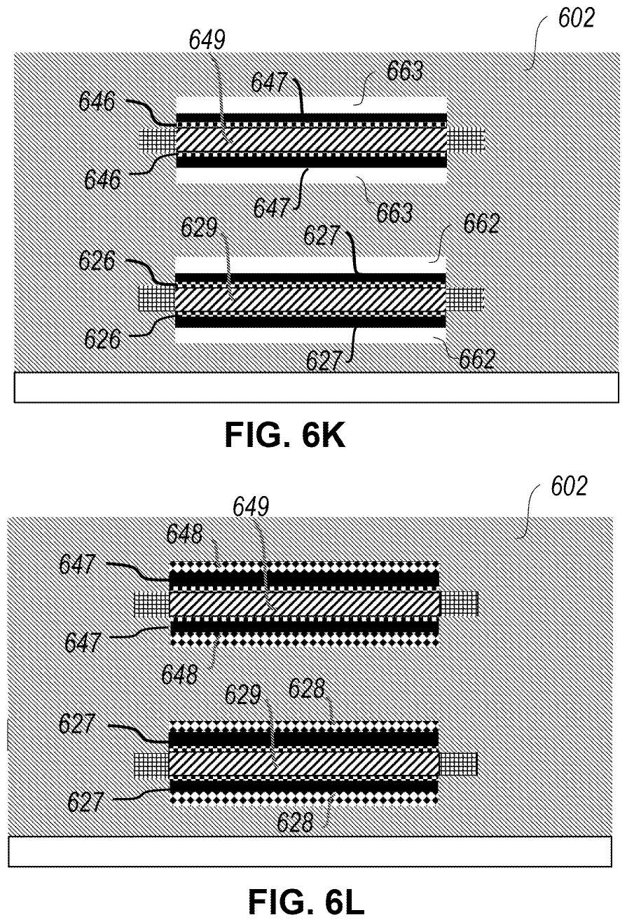

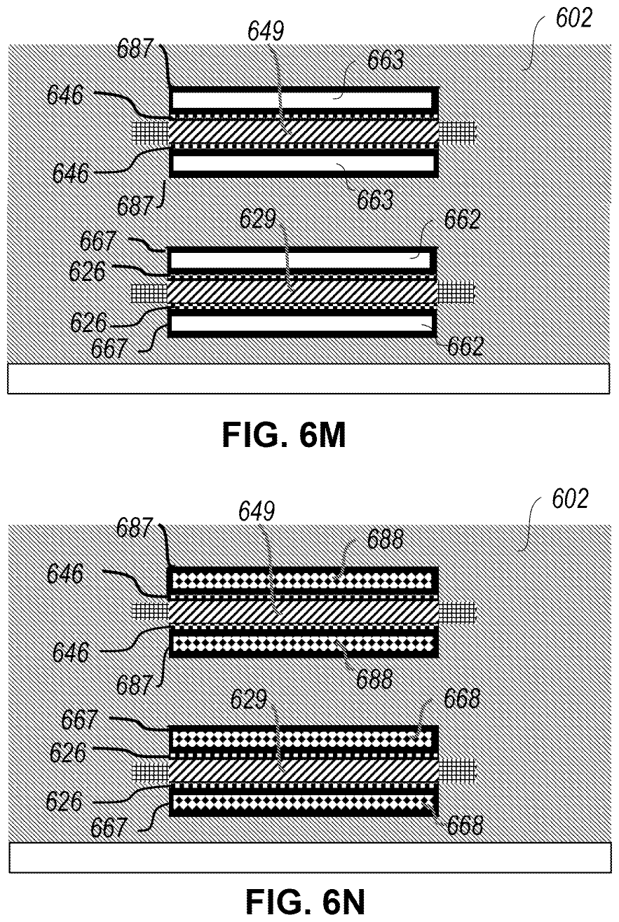

FIGS. 6A-6N show cross-sectional views of a semiconductor device being manufactured at different stages of the process of FIGS. 4A-4D, in accordance with some embodiments. Operations of the process 400 associated with cross-sectional views of an example semiconductor device at various fabrication stages as shown in FIGS. 6A-6N, respectively, are described in further detail herein below. Referring to FIGS. 6A-6N, some embodiments relate to methods for forming 360-degree 2D channel in an N device tall stack (e.g., N=2) in one process. Operations of the process 400 associated with cross-sectional views of an example semiconductor device at various fabrication stages as shown in FIGS. 6A-6N, respectively, are described in further detail herein below.

Corresponding to operation S401, FIG. 6A illustrates a resulting cross-sectional view of the semiconductor device after forming, on a substrate 603, a stack including one or more layers of a first material 601, one or more layers of a second material 602, a first sacrificial material 621, a second sacrificial material 622, a third sacrificial material 623, a fourth sacrificial material 624, and a cap layer 655. The stack may be created or formed on the substrate 603. A selective region may be formed using the first material 601, and a de-selective (non-selective) region may be formed using the second material 602. A 2D material (e.g., 2D material 626 in FIG. 6J) may be formed on a selective region (e.g., top and bottom regions of the first dielectric material 629 in FIG. 6J) with a de-selective region enclosure (e.g., a region enclosed by the second material 602 around the first dielectric material 629 in FIG. 6J). In some embodiments, each of the first to fourth sacrificial materials 621, 622, 623, 624 may include nitride. The first material 601 and the second material 602 may be different from each other. For example, the first material 601 may be silicon oxide (SiO₂) or transition metal oxides such as MoO₃, Nb₂O₅, or WO₃, and the second material 602 may be Al₂O₃ or HfO₂.

Corresponding to operation S402, FIG. 6B illustrates a resulting cross-sectional view of the semiconductor device after (1) forming a photoresist mask 656 on the stack (see FIG. 6A) and (2) etching the stack to define width and length of a of the first material 601 (a majority of which will be surrounded by a 2D material) using the photoresist mask 656. In some embodiments, the photoresist mask 656 may be formed on the cap layer 655.

Corresponding to operation S403, FIG. 6C illustrates a resulting cross-sectional view of the semiconductor device after (1) removing the photoresist mask 656 (see FIG. 6B), (2) performing deposition of the second material 602 (as a de-selective area), and (3) performing chemical-mechanical polishing (CMP).

Corresponding to operation S404, FIG. 6D illustrates a resulting cross-sectional view of the semiconductor device after (1) forming one or more photoresist masks 657 and (2) etching the second material 602 and/or the stack to open up a future source (end) region 658 and a future drain (end) region 659.

Corresponding to operation S405, FIG. 6E illustrates a resulting cross-sectional view of the semiconductor device after (1) removing the one or more photoresist masks 657 (see FIG. 6D), (2) performing an indent etch on each of the first to fourth sacrificial materials to remove end portions thereof 660, (3) performing deposition of the second material (as a de-selective area) in the removed end portions 660 such that a first dielectric material 629 (formed of the first material 601) having a central portion with top and bottom surfaces thereof overlaid by the first and second sacrificial materials 651, 652, respectively, and a second dielectric material 649 (formed of the first material 601) having a central portion with top and bottom surfaces thereof overlaid by the third and fourth sacrificial materials 653, 654, respectively, and (4) etching de-selective areas or regions (e.g., the second material 602 at both ends of the dielectric materials 629 and 649) using a hard mask to be aligned to edges of the hard mask. The hard mask may be a nitride, oxide, or metal. The cap layer 655 may be used as a hard mask. The central portion of the dielectric material 629 may include the first material 601.

Corresponding to operation S406, FIG. 6F illustrates a resulting cross-sectional view of the semiconductor device after (1) replacing end portions of the first dielectric material 629 with a first source metal 624 and a first drain metal 625, respectively, and (2) replacing end portions of the second dielectric material 649 with a second source metal 644 and a second drain metal 645, respectively. In some embodiments, the first material (as a selective area) at the end portions of the first dielectric material 629 may be selectively indent-etched, followed by performing metal depositions to form the first source metal 624 and the first drain metal 625. Similarly, the second material (as a selective area) at the end portions of the second dielectric material 649 may be selectively indent-etched, followed by performing metal depositions to form the second source metal 644 and the second drain metal 645. Subsequently, the first source metal 624 and first drain metal 625 may be etched using a hard mask to be aligned to edges of the hard mask. Similarly, the second source metal 644 and second drain metal 645 may be etched using a hard mask to be aligned to edges of the hard mask. The cap layer 655 may be used as a hard mask.

Corresponding to operation S407, FIG. 6G illustrates a resulting cross-sectional view of the semiconductor device after (1) removing the cap layer 655 (see FIG. 6F), (2) performing deposition of the second material 602 (as a de-selective area) in the removed area, and (3) performing CMP.

Corresponding to operation S408, FIG. 611 illustrates a resulting cross-sectional view of the semiconductor device after (1) forming one or more photoresist masks 661 and (2) etching a resultant structure of operation S407 using the one or more photoresist masks 661 configured to open up a perimeter of the central portion of the first dielectric material 629 and a perimeter of the central portion of the second dielectric material 649. For example, the photoresist masks 661 can cause at least four surfaces of the central portion of the first dielectric material 629 (e.g., top and bottom surfaces of the first dielectric material 629 that are in contact with the first and second sacrificial materials 651 and 652, respectively, and sidewalls of first dielectric material 629 that face toward and away from the plane) to be exposed after removing the first and second sacrificial materials 651 and 652, which will be discussed below. Similarly, the photoresist masks 661 can cause at least four surfaces of the central portion of the second dielectric material 629 to be exposed after removing the third and fourth sacrificial materials 653 and 654.

Corresponding to operation S409, FIG. 61 illustrates a resulting cross-sectional view of the semiconductor device after (1) exposing the central portion of the first dielectric material 629 at least by removing the first sacrificial material 651 and the second sacrificial material 652 (see FIG. 611) such that a cavity 662 of the second material 602 that surrounds the central portion of the first dielectric material 629 (e.g., 360 degree) can be formed, (2) exposing the central portion of the second dielectric material 649 at least by removing the third sacrificial material 653 and the fourth sacrificial material 654 (see FIG. 611) such that a cavity 663 of the second material 602 that surrounds the central portion of the second dielectric material 649 (e.g., 360 degree) can be formed, and (3) removing the one or more photoresist masks 661 (see FIG. 611). In this manner, the first material 601 (as a selective area) of the central portion of the first dielectric material 629 may be exposed 360 degree in the cavity 662 of the second material (as a de-selective area) to perform a 2D material deposition in operation S410. Similarly, the first material 601 (as a selective area) of the central portion of the second dielectric material 649 may be exposed 360 degree in the cavity 663 of the second material (as a de-selective area) to perform a 2D material deposition in operation S410.

Corresponding to operation S410, FIG. 6J illustrates a resulting cross-sectional view of the semiconductor device after (1) selectively growing a first 2D material 626 to be disposed around the central portion of the first dielectric material 629, and (2) selectively growing a second 2D material 646 to be disposed around the central portion of the second dielectric material 649. The first 2D material 626 may be selectively grown on the first material 601 (of the central portion of the first dielectric material 629). Similarly, the second 2D material 646 may be selectively grown on the first material 601 (of the central portion of the second dielectric material 649) The deposition of the first 2D material 626 may be performed on a selective region of the first material 601 (of the central portion of the first dielectric material 629). Similarly, the deposition of the second 2D material 646 may be performed on a selective region of the first material 601 (of the central portion of the second dielectric material 649). The deposition of the first 2D material 626 may be performed by atomic layer deposition (ALD). In some embodiments, the first 2D material 626 does not contact the second material 602. Similarly, the deposition of the second 2D material 646 may be performed by ALD such that the second 2D material 646 does not contact the second material 602. Some example 2D materials for use in forming the channel include, but are not limited to, WS₂, WSe₂, WTe₂, MoS₂, MoSe₂, MoTe₂, HfS₂, ZrS₂, TiS₂, GaSe, InSe, phosphorene, and other similar materials.

In one embodiment, the process 400 may further include operations S411-1 and S412-1 as shown in FIG. 4C. As a result of operations S411-1 and S412-1, the process 400 may form a semiconductor device similar to the device 500 as shown in FIG. 5A.

Corresponding to operation S411-1, FIG. 6K illustrates a resulting cross-sectional view of the semiconductor device after (1) selectively growing a first high-k dielectric 627 to be disposed around the first 2D material 626 (e.g., 360 degrees) and (2) selectively growing a second high-k dielectric 647 to be disposed around the second 2D material 646 (e.g., 360 degrees). In some embodiments, a 360-degree deposition of the first high-k gate dielectric 627 may be performed on the first 2D material 626. Similarly, a 360-degree deposition of the second high-k gate dielectric 647 may be performed on the second 2D material 646.

Corresponding to operation S412-1, FIG. 6L illustrates a resulting cross-sectional view of the semiconductor device after (1) growing a first gate (electrode) metal 628 to be disposed around the first high-k dielectric 627 (e.g., 360 degrees) and (2) growing a second gate (electrode) metal 648 to be disposed around the second high-k dielectric 647 (e.g., 360 degrees). In some embodiments, a 360-degree deposition of the first gate electrode metal 628 may be performed on the first high-k gate dielectric 627. Similarly, a 360-degree deposition of the second gate electrode metal 648 may be performed on the second high-k gate dielectric 647.

Alternatively, the process 400 may include operations S411-2 and S412-2 as shown in FIG. 4D. As a result of operations S411-2 and S412-2, the process 400 may form a semiconductor device similar to the device 550 (see FIG. 5B).

Corresponding to operation S411-2, FIG. 6M illustrates a resulting cross-sectional view of the semiconductor device after (1) non-selectively growing a first high-k dielectric 667 on the second material 602 (as a de-selective area) on the cavity 662 of the second material 602 (e.g., 360 degrees), and (2) non-selectively growing a second high-k dielectric 687 on the second material 602 (as a de-selective area) on the cavity 663 of the second material 602 (e.g., 360 degrees). A portion of the first high-k dielectric 667 may be deposited on the first 2D material 626. Similarly, a portion of the second high-k dielectric 687 may be deposited on the second 2D material 646. The non-selective deposition may be ALD deposition. For example, ALD deposition of the first high-k gate dielectric 667 may be performed on the cavity 662 of the second material 602 (as a de-selective area). Similarly, ALD deposition of the second high-k gate dielectric 687 may be performed on the cavity 663 of the second material 602 (as a de-selective area)

Corresponding to operation S412-2, FIG. 6N illustrates a resulting cross-sectional view of the semiconductor device after (1) growing a first gate (electrode) metal 668 in the cavity 662 of the second material 602 (e.g., 360 degrees), and (2) growing a second gate (electrode) metal 688 in the cavity 663 of the second material 602 (e.g., 360 degrees). In some embodiments, a 360-degree deposition of the first gate electrode metal 668 may be performed in the first high-k gate dielectric 667. Similarly, a 360-degree deposition of the second gate electrode metal 688 may be performed in the second high-k gate dielectric 687.

Referring to FIGS. 6A-6N, some embodiments relate to methods for forming 360-degree 2D channels (e.g., first and second 2D materials 626, 646) in an N device tall stack (e.g., N=2) in one process. In some embodiments, selective and de-selective (or non-selective) ALD deposition of 360-degree 2D channels may be performed. Some embodiments relate to methods for forming 360-degree 2D channels (e.g., first and second 2D materials 626, 646) by performing a selective ALD deposition (see FIG. 6J) and a de-selective ALD deposition (see FIG. 6M) in a horizontal nanosheet with two devices (e.g., two transistors 520, 540 in FIG. 5A or two transistors 560, 580 in FIG. 5B), using two different dielectric materials (e.g., first material 601 and second material 602). For example, silicon oxide (SiO₂), or transition metal oxides such as MoO₃, Nb₂O₅, or WO₃ may be used as the first material 601 in a selective area (or region) for growing 2D materials, while Al₂O₃ or HfO₂ may be used as the second material 602 in a de-selective area (or region) for effectively blocking the growth of 2D materials.

Some embodiments relate to methods for utilizing an enclosure of a cavity of a de-selective (non-selective) area (e.g., cavity 662, 663 in FIGS. 6I-6K and 6M) to perform an area-selective deposition of a 2D channel (see FIG. 6J) in a gate-all-around (GAA) nanosheet (e.g., 360-degree deposition of gate electrode metals 628, 648, 668, 688 in FIGS. 6L and 6N. 2D materials (e.g., first and second 2D materials 626, 646) may be selectively deposited or grown in selective areas (e.g., first material 601) of two material system including (1) the selective area (or region) and (2) a de-selective area (or region), e.g., second material 602. In some embodiments, a selective area and a de-selective area may be formed using two different dielectric materials as described above. In some embodiments, 2D materials may be formed in a selective area of a SiO₂ carrier nanosheet with enclosure of Al₂O₃ as a de-selective (or non-selective) area, using ALD deposition of the 2D materials. For example, referring to FIG. 6J, ALD deposition of the 2D materials 626, 646 may be performed on selective areas of the first material 601 (e.g., SiO₂) with enclosure of de-selective areas of the second material 602 (e.g., Al₂O₃).

Some embodiments relate to methods for forming 360-degree 2D channels (e.g., 2D materials 626, 646) by performing a selective ALD (see FIG. 6J) and a de-selective ALD deposition (see FIG. 6M) in a horizontal nanosheet with multiple devices (e.g., transistors 520, 540 in FIG. 5A or transistors 560, 580 in FIG. 5B), using selective areas of the first material (e.g., SiO₂) and de-selective areas of the second material (e.g., Al₂O₃).

Methods illustrated in FIG. 6A to FIG. 6N may be used to form stacks of transistors. In order to form a CFET structure in which two devices (e.g., top and bottom transistors) have opposite conductive types (a P-type or N-type), a method of masking the two devices or materials thereof may be used to achieve a high level of selective deposition qualities. In some embodiments, certain sections may be masked off using an opening in a stacking direction (e.g., opening 658 in FIG. 6D). For example, in order to form a bottom device, after forming a stack (see FIG. 6A to FIG. 6C), a dielectric material (“DM1”) can be formed in the bottom half of the opening, and a protective layer of another dielectric material (“DM2”) can be formed in the upper half of the opening. To do so, DM1 can be deposited in the opening using any suitable material deposition technique. Then, the DM1 can be directionally etched to be a level above halfway through the stack of materials so that the portion of the opening corresponding to the upper device can be etched. Then, a (relatively thin) layer of DM2 can be deposited in the openings, using any suitable material deposition technique (e.g., ALD, CVD, PVD, PECVD, etc.). DM2 can be deposited such that it does not entirely fill the upper half of the openings, and instead acts as a protective barrier for the stack of layers. DM2 can then be directionally etched to expose DM1 in the openings. Then, a process for forming the bottom device may be performed using the bottom half of the opening while the upper half of the opening is isolated (by the DM2 barrier) from the stack of layers for the upper device. In this manner, the stack of layers for the upper device may be protected during the process of forming the bottom device. After forming the bottom device, the DM2 barrier can be removed and a process for forming the upper device, which is similar to that of forming the bottom device, may be performed with the remaining stack of layers (which has been protected while the bottom device was formed) using the upper half of the opening.

Methods according to some embodiments may be applied to a flow of forming any 2D material in a GAA 3D stacked nanosheet. In some embodiments, 2D materials may be formed in a GAA 3D stacked nanosheet included in a complementary vertical field effect transistor (CFET) structure in which two transistors have opposite conductive types (a P-type or N-type). For example, referring to FIG. 5A, the device 500 may be a CFET including (1) the transistor 520 of one of P-type or N-type and (2) the transistor 540 of the other of P-type or N-type. Similarly, referring to FIG. 5B, the device 550 may be a CFET including (1) the transistor 560 of one of P-type or N-type and (2) the transistor 580 of the other of P-type or N-type.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A method for fabricating semiconductor devices, comprising:
forming a dielectric having a central portion with top and bottom surfaces thereof;
forming a first sacrificial material and a second sacrificial material on the top and bottom surfaces, respectively, of the dielectric;
replacing end portions of the dielectric with a first source/drain (S/D) metal and a second S/D metal;
exposing the central portion of the dielectric at least by removing the first sacrificial material and second sacrificial material; and
selectively growing a two-dimensional (2D) material around the central portion of the dielectric.

2. The method of claim 1, wherein selectively growing a 2D material comprises:
performing atomic layer deposition (ALD) of the 2D material on a 2D selective region with a de-selective region enclosure, wherein
the 2D material includes WS₂,
the 2D selective region is a silicon dioxide (SiO₂) carrier nanosheet, and
the de-selective region enclosure includes aluminium oxide (Al₂O₃).

3. The method of claim 1, wherein the 2D material is a material selected from the group consisting of: WS₂, WSe₂, WTe₂, MoS₂, MoSe₂, MoTe₂, HfS₂, ZrS₂, TiS₂, GaSe, InSe, phosphorene, and combinations thereof.

4. The method of claim 1, further comprising:
selectively growing a high-k dielectric around the 2D material; and
growing a gate metal around the high-k dielectric.

5. The method of claim 1, wherein
exposing the central portion includes forming a cavity defined by a second dielectric that surrounds the central portion, and wherein the 2D material is not formed on the second dielectric.

6. The method of claim 5, further comprising:
non-selectively growing a high-k dielectric on the second dielectric; and
growing a first gate metal in the cavity of the second dielectric.

7. The method of claim 5, further comprising:
forming a third dielectric having a central portion with top and bottom surfaces thereof;
forming a third sacrificial material and a fourth sacrificial material on the top and bottom surfaces, respectively, of the third dielectric;
replacing end portions of the second dielectric with a third source/drain (S/D) metal and a fourth S/D metal, respectively;
exposing the central portion of the dielectric at least by removing the third sacrificial material and fourth sacrificial material; and
selectively growing a 2D material around the central portion of the second dielectric.

8. The method of claim 7, wherein exposing the central portion of the second dielectric includes forming a cavity of the third dielectric that surrounds the central portion of the second dielectric, wherein the second 2D material does not contact the third dielectric.

9. The method of claim 5, wherein the dielectric is silicon dioxide (SiO₂), and the second dielectric is aluminium oxide (Al₂O₃).

10. A semiconductor device, comprising:
a transistor structure including:
a first source/drain (S/D) metal;
a second S/D metal;
a dielectric containing silicon extending between and coupled to the first S/D metal and second S/D metal;
a two-dimensional (2D) material around the dielectric;
a high-k dielectric around the 2D material; and
a gate metal around the high-k dielectric.

11. The semiconductor device of claim 10, wherein the 2D material is a material selected from the group consisting of: WS₂, WSe₂, WTe₂, MoS₂, MoSe₂, MoTe₂, HfS₂, ZrS₂, TiS₂, GaSe, InSe, phosphorene, and combinations thereof.

12. The semiconductor device of claim 10, wherein the transistor structure is embedded in a second dielectric comprising aluminum.

13. The semiconductor device of claim 12, wherein the 2D material directly contacts a majority portion of the dielectric.

14. The semiconductor device of claim 12, further comprising:
a second transistor including:
a third source/drain (S/D) metal;
a fourth S/D metal;
a second dielectric extending between and coupled to the third S/D metal and fourth S/D metal;
a second 2D material around the second dielectric;
a second high-k dielectric around the second dielectric; and
a second gate metal around the second high-k dielectric.

15. The semiconductor device of claim 14, wherein the second transistor is embedded in the second dielectric.

16. The semiconductor device of claim 14, wherein the second transistor is disposed above the first transistor, and the first and second transistors have opposite conductive types.

17. The semiconductor device of claim 12, wherein the dielectric is silicon dioxide (SiO₂), and the second dielectric is aluminium oxide (Al₂O₃).

18. A semiconductor device, comprising:
a first transistor and a second transistor,
the first transistor includes:
a first dielectric;
a first two-dimensional (2D) material around the first dielectric;
a first source/drain (S/D) metal coupled to one end of the first 2D material;
a second S/D metal coupled to the other end of the first 2D material; and
a first gate metal around the first 2D material,
the second transistor includes:
a second dielectric;
a second 2D material around the second dielectric;
a second source metal coupled to one end of the second 2D material;
a second drain metal coupled to the other end of the second 2D material; and
a second gate metal around the second 2D material,
the second transistor is disposed above the first transistor, and the first and second transistors have opposite conductive types.

19. The semiconductor device of claim 18, wherein
the first transistor further includes a first high-k dielectric around the first 2D material,
the first gate metal around the first high-k dielectric,
the second transistor further includes a second high-k dielectric around the second 2D material, and
the second gate metal around the second high-k dielectric.

20. The semiconductor device of claim 18, the first transistor and the second transistor are embedded in a third dielectric.
